(19) United States
(12) Patent Application Publication
(10) Pub. No.: US 2026/0126477 A1
(43) Pub. Date: May 7, 2026

(54) Apparatus and a Method for Determining an Operational State of a Rotating Machine

(71) Applicant: ABB Schweiz AG, Baden (CH)

(72) Inventors: Pavankumar CR, Mandya (IN); Prasad Mulay, Nashik (IN); Prasanth BL, Hosur (IN)

(73) Assignee: ABB Schweiz AG, Baden (CH)

(21) Appl. No.: 19/440,124

(22) Filed: Jan. 5, 2026

Related U.S. Application Data
(63) Continuation of application No. PCT/IB2023/057114, filed on Jul. 11, 2023.

(51) Int. Cl. G01R 19/25; G01R 31/34

(52) U.S. Cl. CPC G01R 19/2513; G01R 31/343

(57) ABSTRACT

Apparatus and method of determining an operational state of a rotating machine. The method comprises receiving a plurality of parameter values corresponding to a plurality of parameters measured by one or more sensors placed in a vicinity of the rotating machine. The plurality of parameter values belong to one or more measurement axes supported by the one or more sensors. The method further comprise selecting a set of parameter values, among the plurality of parameter values, having a maximum value being measured by each sensor and comparing the set of parameter values with corresponding predefined threshold values. Thereafter, the method comprises determining a set of intermediate operational states of the rotating machine based on the comparison and a final operational state of the rotating machine based on the set of intermediate operational states.

### CROSS-REFERENCE TO RELATED APPLICATIONS

The instant application claims priority to International Patent Application No. PCT/IB2023/057114, filed Jul. 11, 2023, which is incorporated herein in its entirety by reference.

### FIELD OF THE DISCLOSURE

The present disclosure generally relates to rotating machines and, more specifically, to systems and methods for monitoring an operational state of the rotating machines.

### BACKGROUND OF THE INVENTION

Rotating electric motors are widely utilized across various industries, including blowers, fans, machine tools, pumps, turbines, power tools, alternators, compressors, rolling mills, ships, movers, paper mills, and many more. The consistent rotation of these motors leads to a gradual reduction in bearing's lifespan and grease quality. Failing to schedule maintenance at the appropriate intervals can result in catastrophic failures of the rotating equipment. To address this issue, sensors such as vibration sensors, magnetic field sensors, and acoustic sensors have been employed, along with signal analysis techniques, to determine the running status of these motors. By analyzing the running statuses of the rotating equipment, it becomes possible to estimate the running duration and offer valuable insights such as regreasing advice and bearing lifetime predictions.

However, in the current industrial scenario, stray vibrations caused by surrounding rotating equipment have a significant influence on the detection of the running status. These vibrations may interfere with the accuracy of the measurements, leading to unreliable results. Moreover, the running status of the motor has traditionally been determined using current sensors, which are not considered a cost-effective solution due to their limitations in accurately assessing the running conditions.

Thus, to overcome these challenges and enhance the maintenance practices associated with rotating electric motors, there is a need for an improved solution. There is a need for techniques that address the issue of stray vibrations, which can hinder the detection of the running status and effectively mitigate their effects.

### BRIEF SUMMARY OF THE INVENTION

In one embodiment of the present disclosure, a method of determining an operational state of a rotating machine is disclosed. The method comprises receiving a plurality of parameter values corresponding to a plurality of parameters measured by one or more sensors placed in a vicinity of the rotating machine, wherein the plurality of parameter values belongs to one or more measurement axes supported by the one or more sensors. The method further comprises selecting a set of parameter values, among the plurality of parameter values, having a maximum value being measured by each sensor and comparing the set of parameter values with corresponding predefined threshold values. Thereafter, the method comprises determining a set of intermediate operational states of the rotating machine based on the comparison; and determining a final operational state of the rotating machine based on the set of intermediate operational states.

### BRIEF DESCRIPTION OF THE SEVERAL VIEWS OF THE DRAWING(S)

FIG. 1 is an exemplary block diagram of an apparatus for determining an operational state of a rotating machine in accordance with an embodiment of the present disclosure.

FIG. 2 is a block diagram of a process for determining an operational state of a rotating machine in accordance with an embodiment of the present disclosure.

FIG. 3 is a flowchart illustrating an exemplary method of determining an operational state of a rotating machine in accordance with some embodiments of the present disclosure.

FIG. 4 is a flowchart illustrating an exemplary method of determining an operational state of a rotating machine, in accordance with some embodiments of the present disclosure.

It should be appreciated by those skilled in the art that any block diagrams herein represent conceptual views of the illustrative systems embodying the principles of the present subject matter. Similarly, it will be appreciated that any flowcharts, flow diagrams, state transition diagrams, pseudo code, and the like represent various processes which may be substantially represented in computer readable medium and executed by a computer or processor, whether or not such computer or processor is explicitly shown.

### DETAILED DESCRIPTION OF THE INVENTION

In the present document, the word “exemplary” is used herein to mean “serving as an example, instance, or illustration.” Any embodiment or implementation of the present subject matter described herein as “exemplary” is not necessarily to be construed as preferred or advantageous over other embodiments.

While the disclosure is susceptible to various modifications and alternative forms, specific embodiment thereof has been shown by way of example in the drawings and will be described in detail below. It should be understood, however, that it is not intended to limit the disclosure to the particular form disclosed, but on the contrary, the disclosure is to cover all modifications, equivalents, and alternatives falling within the spirit and the scope of the disclosure.

The terms “comprise(s)”, “comprising”, “include(s)”, or any other variations thereof, are intended to cover a non-exclusive inclusion, such that a setup, device, apparatus, system, or method that comprises a list of components or steps does not include only those components or steps but may include other components or steps not expressly listed or inherent to such setup or device or apparatus or system or method. In other words, one or more elements in a device or system or apparatus proceeded by “comprises . . . a” does not, without more constraints, preclude the existence of other elements or additional elements in the system.

In the following detailed description of the embodiments of the disclosure, reference is made to the accompanying drawings that form a part hereof, and in which are shown by way of illustration of specific embodiments in which the disclosure may be practiced. These embodiments are described in sufficient detail to enable those skilled in the art to practice the disclosure, and it is to be understood that other embodiments may be utilized and that changes may be made without departing from the scope of the present disclosure. The following description is, therefore, not to be taken in a limiting sense. In the following description, well known functions or constructions are not described in detail since they would obscure the description with unnecessary detail.

To address the above-mentioned challenges, a non-invasive sensor-based solution is proposed in the present disclosure. By utilizing sensor data, various signal processing techniques may be derived to accurately determine the running status of the motor in a cost-effective manner. These techniques may comprise analysing parameters such as root mean square (RMS) magnetic flux, Signal to Noise Ratio (SNR), Harmonic energy ratio, velocity RMS, Ratio of peak magnetic flux to time domain RMS of magnetic flux, and Ratio of peak acceleration to velocity RMS, but not limited thereto. These disclosed techniques mitigate the influence of adjacent motors, thereby provide accurate determination of the running status of the rotating machine.

By leveraging the non-invasive sensors and developing advanced signal processing techniques, the present disclosure aims to provide a cost-effective and accurate solution for determining the running status of rotating electric motors. The disclosed techniques overcome the limitations of current sensor-based approaches and enable proactive maintenance planning, reduction in downtime, and improved overall operational efficiency and reliability of rotating electric motors.

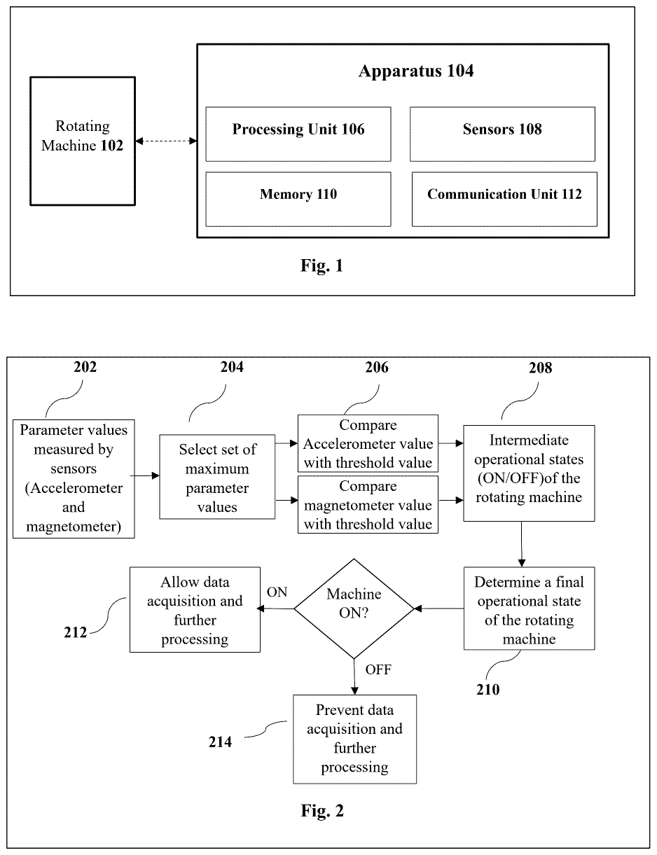

FIG. 1 is a block diagram for a system for monitoring an operational state of a rotating machine according to an embodiment of the present disclosure. As shown in FIG. 1, the system 100 may comprise the rotating machine 102 and a monitoring apparatus 104 for determining the operational state of the rotating machine 102. The monitoring apparatus 104 may comprise a processing unit 106, sensors 108 and memory 110 and a communication unit 112. The processing unit 106 may comprise at least one processor which may include, but not restricted to, microprocessors, microcomputers, micro-controllers, central processing units, state machines, logic circuitries, and/or any devices that manipulate signals based on operational instructions. In an embodiment of the present disclosure, the processing unit 106 may also be implemented as a combination of devices, e.g., a combination of a plurality of microprocessors or any other such configuration. The at least one memory 110 may be communicatively coupled to the processing unit 106 and may comprise various instructions. The at least one memory 110 may include a Random-Access Memory (RAM) unit and/or a non-volatile memory unit such as a Read Only Memory (ROM), optical disc drive, magnetic disc drive, flash memory, Electrically Erasable Read Only Memory (EEPROM), a memory space on a server or cloud and so forth. The processing unit 106 may be configured to execute one or more instructions stored in the memory 110. The memory 110 may also store data processed by the processing unit 106 and sensors 108. The communication unit 112 may be a wireless communication unit which may be used to transmit or receive any sort of data or information to external components. The communication unit 112 enables the apparatus 104 to exchange data with cloud (not shown in figures) for further processing.

In an embodiment, the monitoring apparatus 104 (also interchangeably used as apparatus 104) may be a portable device. In an embodiment, the apparatus 104, along with the processing unit 106, sensors 108, and memory 110 may be easily held and carried by an operator, in order to allow unrestricted movement around the rotating machine 102. The operator can conveniently position the apparatus 104 at different positions with respect to the machine to be tested or monitored. In a plant where the rotating machine is located, there may be other machines situated in various positions relative to the rotating machine. In some cases, these machines may be positioned close to the rotating machine, leaving no available space for mounting the monitoring apparatus 104. By integrating the sensors 108 with the portable monitoring apparatus 104, the operator has the flexibility to place the monitoring apparatus 104 without any obstacles, effectively addressing different scenarios. This adaptability proves valuable in carrying out the monitoring process, accommodating the diverse machine arrangements found within a plant.

In an embodiment, the sensors 108 may comprise, but not limited to, a magnetometer, a torque sensor, a microphone, and an accelerometer. The sensors 108 may be used to collect measurement data associated with the rotating machine. In an embodiment, the magnetometer may be used to collect information about the magnetic fields surrounding the rotating machine. This data is valuable in assessing magnetic interference, detecting anomalies, or monitoring magnetic properties. Further, the torque sensor allows the precise measurement and monitoring of the rotational force of the rotating machine. By accurately quantifying torque, the torque sensor provides insights into the performance, efficiency, and mechanical stresses experienced by the machine. This information may be used for predictive maintenance, identifying potential issues, or optimizing operational parameters. Further, the microphone may enable the apparatus 104 to capture airborne acoustics. The microphone may convert the audio signal into electrical signals, which enables the detection of audible vibrations and noises emitted by the rotating machine. Furthermore, the accelerometer may be used to measure acceleration, vibrations, and motion. By utilizing this sensor, the monitoring apparatus 104 may capture and interpret the dynamic movements and vibrations exhibited by the rotating machine. This allows for the assessment of structural integrity, mechanical vibrations, or any deviations from normal operating conditions. Thus, by selecting one or more sensors, the monitoring apparatus 104 may provide a comprehensive and accurate analysis of the electric machine's operational state, health, and surrounding environment.

In an embodiment, the apparatus 104 comprising the one or more sensors 108 may be placed within the vicinity of the rotating machine to measure the data associated with the machine's operation. The data may comprise, for example, magnetic field data, electric field data, and vibration data. The measured data may be processed by the processing unit 106 to determine a plurality of parameters values associated with an operation of the rotating machine 102 based on the measurement data obtained from the rotating machine. In an exemplary embodiment, the plurality of parameters may comprise root mean square (RMS) magnetic flux, Signal to Noise Ratio (SNR), Harmonic energy ratio, velocity RMS, Ratio of peak magnetic flux to time domain RMS of magnetic flux, and Ratio of peak acceleration to velocity RMS, but not limited thereto. In a non-limiting exemplary embodiment, the apparatus 104 may comprise a dedicated unit to calculate the value of plurality of parameters by processing the aforementioned data provided by the sensors 108. In an embodiment, the sensor 108 may be multi-axis sensors such as tri-axial sensor but not limited thereto. Thus, the plurality of parameter values may belong to one or more measurement axes supported by the sensors 108.

In an embodiment, if a particular machine is in ON state, then it will have rotating magnetic flux present around it. Thus, it can be determined whether the magnetic flux is beyond a certain threshold. Regarding, the ratio of peak in magnetic spectrum to time domain RMS of magnetic flux, it is determined for the dominant peak of the magnetic spectrum and whether it is greater than a desired threshold limit when compared with overall magnetic RMS. Further, the velocity RMS will also be higher than a certain limit when a machine is ON. Thus it can be determined whether velocity RMS is above a certain threshold or not. Further, it is also checked if the dominant peak in the acceleration spectrum is greater than a certain limit as compared to velocity RMS. Regarding the harmonic energy ratio, for the running speed of the rotation machine, speed Harmonic energy (i.e., Square root of sum of squares of maximum velocity amplitudes of all speed harmonics) and total energy (i.e., square root of sum of squares of all velocity amplitudes of velocity vibration spectrum) are determined and thereafter Harmonic energy ratio (i.e., ratio of Harmonic energy and Total energy) is determined. Regarding the SNR, for the running speed of the rotation machine, Peak energy (i.e., the sum of squares of velocity amplitude of speed harmonics) and Noise energy (i.e., the square root of the sum of squares of all values in the array of velocity amplitudes excluding the speed harmonics amplitudes) are computed and then the SNR is the ratio of Peak energy and Noise energy. Further, regarding the ratio of peak in magnetic spectrum to time domain RMS of magnetic flux, the dominant peak the magnetic spectrum is determined and it is determined whether it is greater than a desired threshold limit when compared with overall magnetic RMS.

Upon obtaining the values of the plurality of parameters, the processing unit may compare the plurality of parameter values with corresponding predefined threshold values. In an embodiment, while measuring data associated with the rotating machine using the sensors 108, it is important to mitigate the effect of neighbouring machines. It is possible that the measurements obtained from the sensors 108 may be influenced by the operation of neighbouring machines or external factors. To address this issue, the predefined threshold values are utilized. The thresholds may serve as reference points or limits against which the measured parameter values are compared. By comparing the parameter values with the predefined thresholds, it becomes possible to filter out the effects of neighbouring machines or external factors.

Based on the comparison, the processing unit may generate a comparison matrix, which comprises a plurality of indicator values corresponding to the plurality of parameter values. Each indicator value indicates whether corresponding parameter value is less than, equal to or greater than a corresponding threshold value. In a non-limiting exemplary embodiment, the indicator value may be in the form of “0” and “1”. The “0” indicates that a parameter value is less than a corresponding threshold value, and the “1” indicates that the parameter value is more than or equal to the corresponding threshold value. A skilled person would appreciate the fact that any other indicator values may be used instead of “0” and “1”.

In an embodiment, the processing unit 106 may perform the necessary computations and algorithms to generate the comparison matrix. The comparison matrix may represent the relationship between the measured parameters value and their adherence to the predefined thresholds. The comparison matrix may be an M*N matrix, wherein M represents a number of the plurality of parameters and N represents a number of measurement axes corresponding to the received plurality of parameter values.

In an embodiment, if only accelerometer's data is available, then only following four parameter values may be determined: Harmonic energy ratio, velocity RMS, Ratio of peak magnetic flux to time domain RMS of magnetic flux, and Ratio of peak acceleration to velocity RMS. Accordingly, a matrix of size 4*3 may be generated. The size of the matrix is determined by the combination of the four parameters and three axes, which may vary depending on number of axis the accelerometer sensor supports. Whereas, if only the magnetometer's data is available, then only following two parameter values may be determined: root mean square (RMS) magnetic flux and Signal to Noise Ratio (SNR). Accordingly, a matrix of size 2*3 may be generated. The size of the matrix is determined by the combination of the two parameters and three axes, which may vary depending on number of axis the magnetometer sensor supports. However, if both accelerometer and magnetometer sensor data are available, then the following six parameter values may be determined: root mean square (RMS) magnetic flux, Signal to Noise Ratio (SNR), Harmonic energy ratio, velocity RMS, Ratio of peak magnetic flux to time domain RMS of magnetic flux, and Ratio of peak acceleration to velocity RMS. Accordingly, a matrix of size 6*3 may be generated. The size of the matrix is determined by the combination of the six parameters and three axes.

Further, the processing unit 106 may generate a quality matrix by processing the plurality of indicator values of the comparison matrix. In an embodiment, to generate the quality matrix by processing the plurality of indicator values of the comparison matrix, the processing unit 106 may perform a row-wise comparison and column-wise comparison of each indicator value of the comparison matrix with a subsequent indicator value of the comparison matrix. The processing unit 106 may generate a first matrix by incrementing an indicator value of the first matrix by a first predefined value when the indicator value matches with the subsequent indicator value while performing the row-wise comparison in the first matrix. Further, the processing unit 106 may generate a second matrix by incrementing an indicator value of the first matrix by a second predefined value when the indicator value matches with the subsequent indicator value while performing the column-wise comparison in the first matrix. Thereafter, the processing unit 106 may generate a third matrix by summation of the first matrix and the second matrix.

Thereafter, the processing unit 106 may generate a quality matrix by multiplying indicator values of the third matrix with corresponding weightages. The processing unit 106 may identify a highest indicator value present in the quality matrix and map the highest indicator value of the quality matrix to a corresponding indicator value of the comparison matrix to determine the operational state of the rotating machine. The processing unit 106 may determine the operation state as ON state when the indicator value of the comparison matrix mapped to the highest indicator value is equal to or greater than the threshold value, and may determine the operation state as OFF state when the indicator value of the comparison matrix mapped to the highest indicator value is less than the threshold value.

The embodiments mentioned in paragraphs may be easily understood using the following example. Let's assume that the comparison matric is a 4*3 matrix:

| | | |
|---|---|---|
| 1 | 0 | 1 |
| 0 | 1 | 1 |
| 1 | 0 | 0 |
| 1 | 1 | 0 |

The processing unit 106 may perform the row-wise comparison of each indicator value in the comparison matrix with a subsequent indicator value. When performing the row-wise comparison, if an indicator value in the comparison matrix matches the subsequent adjacent value, the processing unit 106 may increment the indicator value by the first predefined value. Let's assume the first predefined value is 1. In the first row: 1^{st} indicator value (1) is compared with the subsequent indicator value (0), 2^{nd} indicator value (0) is compared with the subsequent indicator value (1), 3^{rd} indicator value (1) is compared with the subsequent indicator value i.e. 1^{st} indicator value (the end of the row, wraps around to the 1^{st} indicator value in the same row).

So, in this case, the comparison would be as follows: 1^{st} indicator value (1) compared with the subsequent indicator value (0) results in a non-match. 2^{nd} indicator value (0) compared with the subsequent indicator value (1) results in a non-match. 3^{rd} indicator value (1) compared with the subsequent indicator value (1) in the same row results in a match.

The row-wise comparison continues for the remaining rows in a similar manner. After performing the row-wise comparison, the processing unit 106 may generate the first matrix, as shown below:

| | | |
|---|---|---|
| 1 | 0 | 2 |
| 0 | 2 | 1 |
| 1 | 2 | 0 |
| 2 | 1 | 0 |

Similar to the row wise comparison, the processing unit 106 may perform the column-wise comparison of each indicator value in the comparison matrix with the subsequent adjacent value in the same column. When performing the column-wise comparison, if an indicator value in the comparison matrix matches the subsequent adjacent value, the processing unit may increment the indicator value by the second predefined value. Let's assume the second predefined value is 2. The processing unit 106 may perform the column-wise comparison for entire matrix (using the above-described technique) and generate the third matrix, as shown below:

| | | |
|---|---|---|
| 1 | 0 | 3 |
| 0 | 1 | 1 |
| 3 | 0 | 2 |
| 3 | 1 | 0 |

After generating the first and second matrix, the processing unit 106 may generate the third matrix by summation of the first matrix and the second matrix, as shown below:

| | | |
|---|---|---|
| 2 | 0 | 5 |
| 0 | 3 | 2 |
| 4 | 2 | 2 |
| 5 | 2 | 0 |

After, generating the third matrix, the processing unit 106 may generate a quality matrix by multiplying indicator values of the third matrix with corresponding weightages. In an example, the weightages may be as shown below:

| | | |
|---|---|---|
| 1 | 0 | 2 |
| 0 | 1 | 0 |
| 1 | 1 | 1 |
| 1 | 2 | 1 |

The quality matrix may be obtained by element-wise multiplication of the third matrix and weightages. The quality matrix is as below:

| | | |
|---|---|---|
| 2 | 0 | 10 |
| 0 | 3 | 0 |
| 4 | 2 | 2 |
| 5 | 4 | 0 |

Thereafter, the processing unit 106 may identify the highest indicator value present in the quality matrix, which is 10. The processing unit 106 may map the highest indicator value of the quality matrix to the corresponding indicator value of the comparison matrix to determine the operational state of the rotating machine. In this example, the indicator value of the comparison matrix mapped to the highest indicator value (10) is 1. Therefore, the processing unit 106 may determine the operational state as “ON state” because the mapped indicator value of comparison matrix is “1”. In this manner, the monitoring apparatus may mitigate the influence on the detection of the running status. The apparatus may accurately monitor the running status of the motor in a cost-effective manner.

In one embodiment, the present disclosure provides an alternative solution to monitor the running status of the rotating machine. the alternative solution provide techniques for determining the operation state of the rotating machine 102 with the following characteristics: independent of setting thresholds, low computation and space complexity, suitable to work on different kinds of machines, different frame sizes and vibration levels, suitable to tackle different environmental and noise conditions like adjacent interference, and detects steady state and transients, but not limited thereto.

A block diagram for monitoring the operational state according to the present embodiment is illustrated in FIG. 2. In this embodiment, the processing unit 106 of the apparatus 104 may receive a plurality of parameter values corresponding to a plurality of parameters measured by one or more sensors placed in a vicinity of the rotating machine, as shown at block 202. In an embodiment, the plurality of parameters may be one or more from a group of: peak to average power ratio (PAPR) measured from the frequency spectrum of the sensor data and is achieved by finding the Peak to average power ratio (PAPR) in a predetermined frequency range of interest but not limited thereto. In another embodiment, the plurality of parameters is selected from a group of: correlation coefficient computed from the predefined range of frequency spectrum of the sensor data between different axis but not limited thereto.

The processing unit 106 may select a set of parameter values, among the plurality of parameter values, having a maximum value being measured by each sensor, as shown at block 204. Further. the processing unit 106 may compare the set of parameter values with corresponding predefined threshold values, as shown at block 206. Thereafter, the processing unit 106 may determine a set of intermediate operational states of the rotating machine based on the comparison, as shown at block 208. The intermediate operational states of the rotating machine may be determined individually using the sensors 108 using a predetermined threshold logic or using a classifier developed using a machine learning technique. In an embodiment, the machine learning model may be developed using algorithm and techniques of TinyML (Tiny Machine Learning) to create a model that can be effectively deployed and executed on an embedded device.

Thereafter, the processing unit 106 may determine a final operational state of the rotating machine based on the set of intermediate operational states, as shown at block 210. Particularly, the processing unit 106 may determine the final operational state as ON state when all of the set of operational states are indicative of the ON state of the rotating machine 102 and may determine the final operational state as OFF state when any of the set of operational states is indicative of the OFF state of the rotating machine 102. After determining the final operation state of the rotating machine 102, the processing unit 106 may allow data acquisition and further processing for monitoring conditions of the rotating machine 102 when the final operational state is the ON state (as shown at block 212), whereas the processing unit 106 may prevent the data acquisition and further processing for monitoring the conditions of the rotating machine 102 when the final operational state is the OFF state (as shown at block 214).

The embodiments mentioned in paragraphs may be easily understood using the following example shown as table-1 below:

TABLE 1

| | Status from | Status from | Motor | | |
|---|---|---|---|---|---|
| | Acceler- | Magne- | ON/OF | Transient | Interference |
| S. No. | ometer | tometer | Status | Status | Status |
| 1. | ON | ON | ON | Steady | ON State |
| | | | | State | |
| 2. | ON | OFF | OFF | OFF-ON | Adjacent |
| | | | | Transition | interference |
| | | | | | due to |
| | | | | | vibration |
| 3. | OFF | ON | OFF | ON-OFF | Adjacent |
| | | | | Transition | interference |
| | | | | | due to |
| | | | | | Electric |
| | | | | | cable |
| 4. | OFF | OFF | OFF | Steady | OFF State |
| | | | | State | |

The above table-1 describes the status obtained from the accelerometer and the status obtained from the magnetometer. The statuses may be either “ON” or “OFF.” As shown in the table, when the status from both the accelerometer and magnetometer indicates the ON state of the rotating machine 102, the machine 102 may be determined as ON. Whereas, if one of these are indicative of the OFF state, the final operational state may be determined as OFF. The table-1 also indicates the transient state of the matter based on the ON and OFF status indicated by the accelerometer and magnetometer.

In this manner, the monitoring apparatus 104 may mitigate the influence on the detection of the running status. The apparatus 104 may accurately monitor the running status of the motor in a cost-effective manner. Further, instead of computing KPIs all the time on the device irrespective of machine's ON/OFF status, the disclosed technique allows the processing only when the machine is in ON condition, which improves the battery life of various processing and the monitoring devices. Further, this technique is independent of setting the thresholds for ON/OFF detection which saves considerable resources.

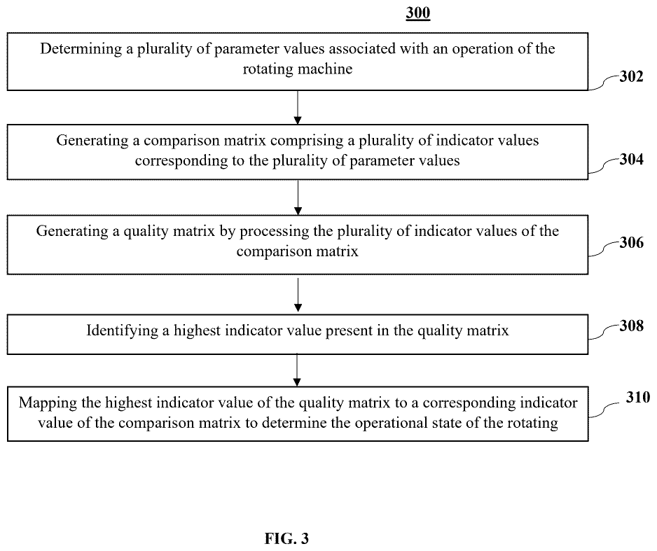

FIG. 3 is a flow diagram illustrating an exemplary method 300 of determining an operational state of a rotating machine. The blocks of the flow diagram shown in FIG. 3 have been arranged in a generally sequential manner for ease of explanation; however, it is to be understood that this arrangement is merely exemplary, and it should be recognized that the processing associated with method 300 (and the blocks shown in FIG. 3) can occur in a different order (for example, where at least some of the processing associated with the blocks is performed in parallel and/or in an event-driven manner).

At step 302, the method recites determining a plurality of parameter values associated with an operation of the rotating machine based on measurement data obtained for the rotating machine. In an embodiment, the measurement data, obtained from the one or more sensors, may be associated with at least one of the magnetic field of the rotating machine and the acceleration of the rotating machine. Further, the plurality of parameter values belongs to one or more measurement axes supported by the one or more sensors. In an embodiment, the one or more sensors may be selected from a group of a magnetometer, torque sensor, microphones, and an accelerometer, but not limited thereto. In another embodiment, the plurality of parameters may comprise one or more of: root mean square (RMS) magnetic flux, Signal to Noise Ratio (SNR), Harmonic energy ratio, velocity RMS, Ratio of peak magnetic flux to time domain RMS of magnetic flux, and Ratio of peak acceleration to velocity RMS, but not limited thereto.

The method at step 304 recites generating a comparison matrix comprising a plurality of indicator values corresponding to the plurality of parameter values. Each indicator value may indicate whether corresponding parameter value is less than, equal to or greater than a corresponding threshold value. the comparison matrix is generated by comparing the plurality of parameter values with the corresponding plurality of threshold values, and generating the comparison matrix based on the comparison. In an embodiment, the comparison matrix may be an M*N matrix, wherein M represents a number of the plurality of parameters and N represents a number of measurement axes corresponding to the received plurality of parameter values.

At step 306, the method recites generating a quality matrix by processing the plurality of indicator values of the comparison matrix. In an embodiment, generating the quality matrix by processing the plurality of indicator values of the comparison matrix may comprise, using the comparison matrix, performing row-wise comparison and column-wise comparison of each indicator value of the comparison matrix with a subsequent indicator value of the comparison matrix. Thereafter, a first matrix may be generated by incrementing an indicator value of the comparison matrix by a predefined value when the indicator value matches with the subsequent indicator value while performing the row-wise comparison in the comparison matrix. Further, a second matrix may be generated by incrementing an indicator value of the comparison matrix by a second predefined value when the indicator value matches with the subsequent indicator value while performing the column-wise comparison in the comparison matrix. Subsequently, a third matrix may be generated by summation of the first matrix and the second matrix. Lastly, the quality matrix may be generated by multiplying the plurality of indicator values of the third matrix with corresponding weightages.

At step 308, the method recites identifying a highest indicator value present in the quality matrix. At step 310, the method recites mapping the highest indicator value of the quality matrix to a corresponding indicator value of the comparison matrix to determine the operational state of the rotating machine. In an embodiment, determining the operational state of the rotating machine comprises: determining the operation state as ON state when the indicator value of the comparison matrix mapped to the highest indicator value is equal to or greater than the threshold value, and determining the operation state as OFF state when the indicator value of the comparison matrix mapped to the highest indicator value is less than the threshold value. In this manner, the method mitigates the influence on the detection of the running status. The apparatus may accurately monitor the running status of the motor in a cost-effective manner.

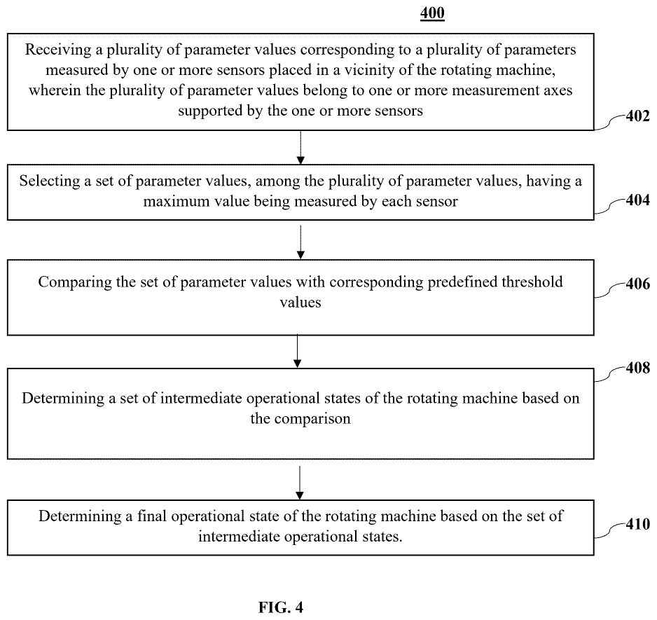

FIG. 4 is a flow diagram illustrating another exemplary method 400 of determining an operational state of a rotating machine. The blocks of the flow diagram shown in FIG. 4 have been arranged in a generally sequential manner for ease of explanation; however, it is to be understood that this arrangement is merely exemplary, and it should be recognized that the processing associated with method 400 (and the blocks shown in FIG. 4) can occur in a different order (for example, where at least some of the processing associated with the blocks is performed in parallel and/or in an event-driven manner).

At step 402, the method recites receiving a plurality of parameter values corresponding to a plurality of parameters measured by one or more sensors placed in a vicinity of the rotating machine, wherein the plurality of parameter values belongs to one or more measurement axes supported by the one or more sensors. In an embodiment, the one or more sensors may be selected from a group of a magnetometer, torque sensor, a microphone, and an accelerometer, but not limited thereto. In another embodiment, the plurality of parameters may be selected from a group of: peak to average power ratio (PAPR) measured from the frequency spectrum of the sensor data and is achieved by finding the Peak to average power ratio (PAPR) in a predetermined frequency range of interest but not limited thereto. In yet another embodiment, the plurality of parameters may be selected from a group of: correlation coefficient computed from the predefined range of frequency spectrum of the sensor data between different axis but not limited thereto.

At step 404, the method recites selecting a set of parameter values, among the plurality of parameter values, having a maximum value being measured by each sensor. At step 406, the method recites comparing the set of parameter values with corresponding predefined threshold values. At step 408, the method recites determining a set of intermediate operational states of the rotating machine based on the comparison. In an embodiment, the intermediate operational states of the rotating machine may be determined individually using the one or more sensors using a predetermined threshold logic or using a classifier developed using a machine learning technique. At step 410, the method recites determining a final operational state of the rotating machine based on the set of intermediate operational states. In an embodiment, the step 410 i.e., determining the final operational state of the rotating machine based on the set of intermediate operational states comprises: determining the final operational state as ON state when all of the set of operational states are indicative of the ON state of the rotating machine and determining the final operational state as OFF state when any of the set of operational states is indicative of the OFF state of the rotating machine.

In an embodiment, the method 400 further comprises performing data acquisition for monitoring conditions of the rotating machine when the final operational state is the ON state and preventing the data acquisition and further processing for monitoring the conditions of the rotating machine when the final operational state is the OFF state.

In this manner, the monitoring apparatus may mitigate the influence on the detection of the running status. The apparatus may accurately monitor the running status of the motor in a cost-effective manner. Further, instead of computing KPIs all the time on the device irrespective of machine's ON/OFF status, the disclosed technique allows the processing only when the machine is in ON condition, which improves the battery life of various processing and the monitoring devices. Further, this technique is independent of setting the thresholds for ON/OFF detection which saves considerable resources.

The above methods 300 and 400 may be described in the general context of computer executable instructions. Generally, computer executable instructions can include routines, programs, objects, components, data structures, procedures, modules, and functions, which perform specific functions or implement specific abstract data types.

The order in which the various operations of the methods are described is not intended to be construed as a limitation, and any number of the described method blocks can be combined in any order to implement the method. Additionally, individual blocks may be deleted from the methods without departing from the spirit and scope of the subject matter described herein. Furthermore, the methods can be implemented in any suitable hardware, software, firmware, or combination thereof.

It may be noted here that the subject matter of some or all embodiments described with reference to FIGS. 1-4 may be relevant for the methods and the same is not repeated for the sake of brevity.

The various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in Figures, those operations may be performed by any suitable corresponding counterpart means-plus-function components.

Furthermore, one or more computer-readable storage media may be utilized in implementing embodiments consistent with the present disclosure. A computer-readable storage medium refers to any type of physical memory on which information or data readable by a processor may be stored. Thus, a computer-readable storage medium may store instructions for execution by one or more processors, including instructions for causing the processor(s) to perform steps or stages consistent with the embodiments described herein. The term “computer-readable medium” should be understood to include tangible items and exclude carrier waves and transient signals, i.e., non-transitory. Examples include Random Access Memory (RAM), Read-Only Memory (ROM), volatile memory, nonvolatile memory, hard drives, Compact Disc (CD) ROMs, Digital Video Disc (DVDs), flash drives, disks, and any other known physical storage media.

Certain aspects may comprise a computer program product for performing the operations presented herein. For example, such a computer program product may comprise a computer readable media having instructions stored (and/or encoded) thereon, the instructions being executable by one or more processors to perform the operations described herein. For certain aspects, the computer program product may include packaging material.

Various components, modules, or units are described in this disclosure to emphasize functional aspects of devices configured to perform the disclosed techniques, but do not necessarily require realization by different hardware units. Rather, as described above, various units may be combined in a hardware unit or provided by a collection of interoperative hardware units, including one or more processors as described above, in conjunction with suitable software and/or firmware.

In a non-limiting embodiment of the present disclosure, the plurality of parameters is selected from a group of: peak to average power ratio (PAPR) measured from the frequency spectrum of the sensor data and is achieved by finding the Peak to average power ratio (PAPR) in a predetermined frequency range of interest.

In yet another non-limiting embodiment of the present disclosure, the plurality of parameters are selected from a group of: correlation coefficient computed from the predefined range of frequency spectrum of the sensor data between different axis.

In yet another non-limiting embodiment of the present disclosure, the intermediate operational states of the rotating machine is determined individually using the one or more sensors using a predetermined threshold logic or using a classifier developed using a machine learning technique.

In yet another non-limiting embodiment of the present disclosure, the determining the final operational state of the rotating machine based on the set of intermediate operational states comprises: determining the final operational state as ON state when all of the set of operational states are indicative of the ON state of the rotating machine, and determining the final operational state as OFF state when any of the set of operational states is indicative of the OFF state of the rotating machine.

In yet another non-limiting embodiment of the present disclosure, the method further comprises performing data acquisition for monitoring conditions of the rotating machine when the final operational state is the ON state; and preventing the data acquisition and further processing for monitoring the conditions of the rotating machine when the final operational state is the OFF state.

In yet another non-limiting embodiment of the present disclosure, a method of determining an operational state of a rotating machine is disclosed. The method comprises determining a plurality of parameter values associated with an operation of the rotating machine based on measurement data obtained for the rotating machine. The method further comprises generating a comparison matrix comprising a plurality of indicator values corresponding to the plurality of parameter values, wherein each indicator value indicates whether corresponding parameter value is less than, equal to, or greater than a corresponding threshold value. Further, the method comprises generating a quality matrix by processing the plurality of indicator values of the comparison matrix, and identifying a highest indicator value present in the quality matrix. The method further comprises mapping the highest indicator value of the quality matrix to a corresponding indicator value of the comparison matrix to determine the operational state of the rotating machine.

In yet another non-limiting embodiment of the present disclosure, the comparison matrix is generated by: comparing the plurality of parameter values with the corresponding plurality of threshold values, wherein the plurality of parameter values belongs to one or more measurement axes supported by one or more sensors providing the measurement data, and generating the comparison matrix based on the comparison.

In yet another non-limiting embodiment of the present disclosure, the plurality of parameters comprises one or more of root mean square (RMS) magnetic flux, Signal to Noise Ratio (SNR), Harmonic energy ratio, velocity RMS, Ratio of peak magnetic flux to time domain RMS of magnetic flux, and Ratio of peak acceleration to velocity RMS.

In yet another non-limiting embodiment of the present disclosure, the comparison matrix is an M*N matrix, wherein M represents a number of the plurality of parameter value and N represents a number of measurement axes corresponding to the received plurality of parameter values.

In yet another non-limiting embodiment of the present disclosure, the measurement data, obtained from the one or more sensors, are associated with at least one of magnetic field of the rotating machine and acceleration of the rotating machine.

In yet another non-limiting embodiment of the present disclosure, generating the quality matrix by processing the plurality of indicator values of the comparison matrix, comprises: using the comparison matrix, performing row-wise comparison and column-wise comparison of each indicator value of the comparison matrix with a subsequent indicator value of the comparison matrix, generating a first matrix by incrementing an indicator value of the comparison matrix by a first predefined value when the indicator value matches with the subsequent indicator value while performing the row-wise comparison in the comparison matrix; and generating a second matrix by incrementing an indicator value of the comparison matrix by a second predefined value when the indicator value matches with the subsequent indicator value while performing the column-wise comparison in the comparison matrix. The method further comprises generating a third matrix by summing the first matrix and the second matrix, and generating the quality matrix by multiplying the plurality of indicator values of the third matrix with corresponding weightages.

In yet another non-limiting embodiment of the present disclosure, determining the operational state of the rotating machine comprises: determining the operation state as ON state when the indicator value of the comparison matrix mapped to the highest indicator value is equal to or greater than the threshold value; and determining the operation state as OFF state when the indicator value of the comparison matrix mapped to the highest indicator value is less than the threshold value.

In yet another non-limiting embodiment of the present disclosure, an apparatus to determine an operational state of a rotating machine is disclosed. The apparatus comprises: a processing unit configured to: receive a plurality of parameter values corresponding to a plurality of parameters measured by one or more sensors placed in a vicinity of the rotating machine, wherein the plurality of parameter values belong to one or more measurement axes supported by the one or more sensors; select a set of parameter values, among the plurality of parameter values, having a maximum value being measured by each sensor; compare the set of parameter values with corresponding predefined threshold values; determine, a set of intermediate operational states of the rotating machine based on the comparison and a final operational state of the rotating machine based on the set of intermediate operational states.

The foregoing summary is illustrative only and is not intended to be in any way limiting. In addition to the illustrative aspects, embodiments, and features described above, further aspects, embodiments, and features will become apparent by reference to the drawings and the following detailed description.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A method of determining an operational state of a rotating machine, the method comprising:
receiving a plurality of parameter values corresponding to a plurality of parameters measured by one or more sensors placed in a vicinity of the rotating machine, wherein the plurality of parameter values belongs to one or more measurement axes supported by the one or more sensors;
selecting a set of parameter values, among the plurality of parameter values, having a maximum value being measured by each sensor;
comparing the set of parameter values with corresponding predefined threshold values;
determining a set of intermediate operational states of the rotating machine based on the comparison; and
determining a final operational state of the rotating machine based on the set of intermediate operational states.

2. The method of claim 1, wherein the plurality of parameters are selected from a group of: peak to average power ratio (PAPR) measured from the frequency spectrum of the sensor data and is achieved by finding the Peak to average power ratio (PAPR) in a predetermined frequency range of interest.

3. The method of claim 1, wherein the plurality of parameters are selected from a group of: correlation coefficient computed from the predefined range of frequency spectrum of the sensor data between different axis.

4. The method of claim 1, wherein intermediate operational states of the rotating machine is determined individually using the one or more sensors using a predetermined threshold logic or using a classifier developed using a machine learning technique.

5. The method of claim 1, wherein determining the final operational state of the rotating machine based on the set of intermediate operational states comprises:
determining the final operational state as ON state when all of the set of operational states are indicative of the ON state of the rotating machine; and
determining the final operational state as OFF state when any of the set of operational states is indicative of the OFF state of the rotating machine.

6. The method of claim 5, further comprising:
performing data acquisition for monitoring conditions of the rotating machine when the final operational state is the ON state; and
preventing the data acquisition and further processing for monitoring the conditions of the rotating machine when the final operational state is the OFF state.

7. A method of determining an operational state of a rotating machine, the method comprising:
determining a plurality of parameter values associated with an operation of the rotating machine based on measurement data obtained for the rotating machine;
generating a comparison matrix comprising a plurality of indicator values corresponding to the plurality of parameter values, wherein each indicator value indicates whether corresponding parameter value is less than, equal to or greater than a corresponding threshold value;
generating a quality matrix by processing the plurality of indicator values of the comparison matrix;
identifying a highest indicator value present in the quality matrix; and
mapping the highest indicator value of the quality matrix to a corresponding indicator value of the comparison matrix to determine the operational state of the rotating machine.

8. The method of claim 7, wherein the comparison matrix is generated by:
comparing the plurality of parameter values with the corresponding plurality of threshold values, wherein the plurality of parameter values belong to one or more measurement axes supported by one or more sensors providing the measurement data; and
generating the comparison matrix based on the comparison.

9. The method of claim 7, wherein the plurality of parameters comprises one or more of: root mean square (RMS) magnetic flux, Signal to Noise Ratio (SNR), Harmonic energy ratio, velocity RMS, Ratio of peak magnetic flux to time domain RMS of magnetic flux, and Ratio of peak acceleration to velocity RMS.

10. The method of claim 7, wherein the comparison matrix is an M*N matrix, wherein M represents a number of the plurality of parameter values and N represents a number of measurement axes corresponding to the plurality of parameter values.

11. The method of claim 7, wherein the measurement data, obtained from the one or more sensors, are associated with at least one of magnetic field of the rotating machine and acceleration of the rotating machine.

12. The method of claim 7, wherein generating the quality matrix by processing the plurality of indicator values of the comparison matrix, comprises:
using the comparison matrix,
performing row-wise comparison and column-wise comparison of each indicator value of the comparison matrix with a subsequent indicator value of the comparison matrix;
generating a first matrix by incrementing an indicator value of the comparison matrix by a first predefined value when the indicator value matches with the subsequent indicator value while performing the row-wise comparison in the comparison matrix; and
generating a second matrix by incrementing an indicator value of the comparison matrix by a second predefined value when the indicator value matches with the subsequent indicator value while performing the column-wise comparison in the comparison matrix;
generating a third matrix by summation of the first matrix and the second matrix; and
generating the quality matrix by multiplying the plurality of indicator values of the third matrix with corresponding weightages.

13. The method of claim 7, wherein determining the operational state of the rotating machine comprises:
determining the operation state as ON state when the indicator value of the comparison matrix mapped to the highest indicator value is equal to or greater than the threshold value; and
determining the operation state as OFF state when the indicator value of the comparison matrix mapped to the highest indicator value is less than the threshold value.

14. An apparatus to determine an operational state of a rotating machine, the apparatus comprises:
a processing unit configured to:
receive a plurality of parameter values corresponding to a plurality of parameters measured by one or more sensors placed in a vicinity of the rotating machine, wherein the plurality of parameter values belongs to one or more measurement axes supported by the one or more sensors;
select a set of parameter values, among the plurality of parameter values, having a maximum value being measured by each sensor;
compare the set of parameter values with corresponding predefined threshold values;
determine, a set of intermediate operational states of the rotating machine based on the comparison; and
determine a final operational state of the rotating machine based on the set of intermediate operational states.
